(19) United States
(12) Patent Application Publication
(10) Pub. No.: US 2025/0321296 A1
(43) Pub. Date: Oct. 16, 2025

(54) ROOM TEMPERATURE QUANTUM SENSORS

(71) Applicant: Toyota Motor Engineering & Manufacturing North America, Inc., Plano, TX (US)

(72) Inventors: Taishi Kimura, Chicago, IL (US); Yukihiro Tadokoro, Ann Arbor, MI (US); Shougo Higashi, Ann Arbor, MI (US); Shahriar Esmaeili, Ann Arbor, MI (US); Paul Donald Schmalenberg, Ann Arbor, MI (US)

(73) Assignee: Toyota Motor Engineering & Manufacturing North America, Inc., Plano, TX (US)

(21) Appl. No.: 18/632,846

(22) Filed: Apr. 11, 2024

(51) Int. Cl. G01R 33/032; G01K 11/12

(52) U.S. Cl. CPC G01R 33/032; G01K 11/12

(57) ABSTRACT

In one form of the present disclosure, a quantum sensor comprises a quantum device. The quantum device comprises gallium nitride (GaN) with a color center with a zero-phonon line (ZPL) between about 900 nanometers (nm) and about 990 nm. The GaN can be doped with silicon (Si) and have low carbon (C) and oxygen (O) impurities. In one example, the quantum device is GaN doped with about 10¹⁶ atoms of Si per cm³, having less than about 8×10¹⁵ C atoms per cm³ and less than about 6×10¹⁵ O atoms per cm³, and a Ga vacancy density less than about 10¹⁶ vacancies per cm³.

### TECHNICAL FIELD

The present disclosure relates generally to quantum sensors, and more particularly, to gallium nitride (GaN) quantum sensors.

### BACKGROUND

Quantum sensors are devices that use properties of quantum mechanics to measure physical properties, which results in quantum sensors achieving more precise measurements than traditional sensing devices. Quantum sensors utilize color centers of materials to measure physical properties. For example, the negatively charged nitrogen-vacancy (NV−) center found in diamonds is used as a quantum sensor, where the NV-quantum sensor can measure physical properties, such as magnetic field strength, electric field strength, temperature, strain, and room temperature. Although the diamond NV-color center is well understood and has advantageous spin properties and a strong optical contrast at room temperature, commercially available diamond crystals are typically less than about 1 cm² in size. Accordingly, it is difficult to produce a cost-effective, large-scale diamond NV-color center quantum sensor.

The present disclosure addresses issues related to forming a cost-effective, scalable quantum sensor, and other issues related to quantum sensors.

### SUMMARY

This section provides a general summary of the disclosure and is not a comprehensive disclosure of its full scope or its features.

In one form of the present disclosure, a quantum sensor comprises a quantum device. The quantum device comprises gallium nitride (GaN) with a color center with a zero-phonon line (ZPL) between about 940 nanometers (nm) and about 960 nm.

In another form of the present disclosure, a quantum sensor comprises a quantum device. The quantum device comprises GaN with a color center with a ZPL between about 900 nanometers (nm) and about 990 nm. Further, the GaN is Si-doped, and the quantum device is configured to operate at between about-40 degrees Celsius (C) and about 100° C.

In still another form of the present disclosure, a quantum sensor comprises a quantum device. The quantum device comprises GaN with a color center with a ZPL between about 949 nanometers (nm) and about 951 nm. The GaN is Si-doped, and has less than about 8×10¹⁵ C atoms per cm³ and less than about 6×10¹⁵ O atoms per cm³. Further, the quantum device is configured to operate between about 15° C. and about 25° C. and to measure at least one of a temperature and a magnetic field strength of a sample.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 is a quantum sensor system that utilizes a gallium nitride (GaN) quantum device according to the teachings of the present disclosure;

FIG. 2 is another quantum sensor system with a sample implanted with a GaN quantum device nanoparticle according to the teachings of the present disclosure;

FIG. 3 is a photoluminescence spectra of a GaN sample measured at room temperature;

FIG. 4 is an optically detected magnetic resonance (ODMR) spectra of the GaN sample of FIG. 3; and

FIG. 5 is a flow chart for a method according to the teachings of the present disclosure.

### DETAILED DESCRIPTION

The present disclosure provides a quantum sensor (also referred to herein simply as “sensor”) and a sensor system configured to measure various physical properties of samples. For example, samples may include biological samples, such as biological cells (e.g., blood cells, skin cells, fat cells, etc.), electrical devices, power devices, catalysts, and/or battery electrolytes. Measured physical properties include, for example, a temperature of the sample, an electric field strength of or in the sample, a magnetic field strength of or in the sample, and a pH of the sample, among others. In one form of the present disclosure, the quantum sensor includes a quantum device, where the quantum device includes gallium nitride (GaN). Not being bound by theory, GaN has desirable properties for quantum sensing. In particular, GaN has readily modifiable electrical conductivity (i.e., both n-type and p-type conductivity, depending on the application), wide bandgap (˜3.4 eV) controllable carrier concentrations, and is non-toxic to biological samples. Further, GaN-based quantum sensors according to the teachings of the present disclosure can be formed using large-diameter wafers and well-established semiconductor technologies. Accordingly, GaN-based quantum sensors according to the teachings of the present disclosure are easier and more cost-effective to manufacture than traditional diamond-based quantum sensors. Moreover, the GaN-based quantum sensors provided by the teachings of the present disclosure include an appropriate zero-phonon line (ZPL) range that can be used for biosensing applications. For example, in one form of the present disclosure, the GaN has a ZPL between about 940 nanometers (nm) and about 960 nm which is suitable for biosensing. These GaN-based quantum sensors can be excited and emit signals to a detector even though the GaN-based sensors are located at the deeper regions of the measuring object (sample) since longer wavelength lasers can be used compared with diamond NV centers that use a 532 nm laser wavelength. Stated differently, longer laser wavelengths allows for deeper penetration depths in biomaterials. It should be understood that a ZPL is the energy difference between an excited state and a ground state of a color center. In addition, a ZPL has a frequency determined by the intrinsic energy difference between the excited state and ground state, as well as by the local environment of the color center.

In one or more variations, the GaN is doped with silicon (Si). For example, in some variations the GaN includes about 10¹⁶ atoms of Si per cubic centimeter (cm³). Further, in one or more forms, the GaN includes less than about 8×10¹⁵ carbon (C) atoms per cm³ and less than about 6×10¹⁵ oxygen (O) atoms per cm³. Additionally, in at least one variation, the Ga vacancy density is less than about 10¹⁶ vacancies per cm³. The concentration of Si, along with the low concentrations of C and O impurity and low Ga vacancy, assist in creating color centers and stabilize the bright state of the color centers with a ZPL being between about 900 nm and about 990 nm, e.g., color centers with a ZPL between about 940 nm and about 960 nm.

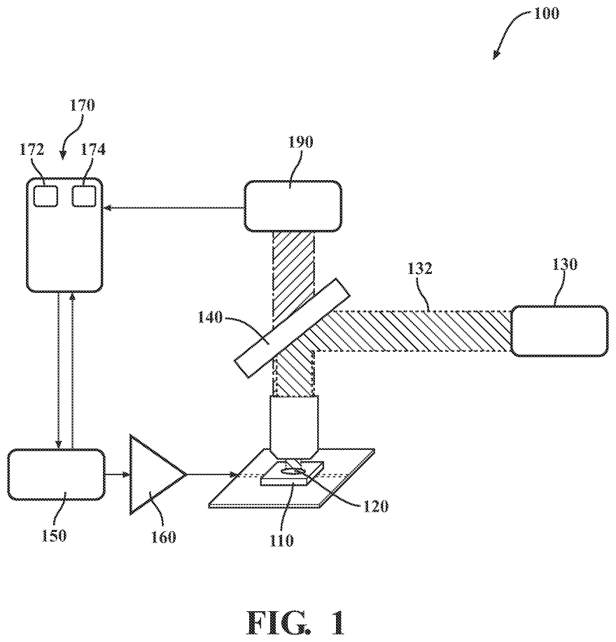

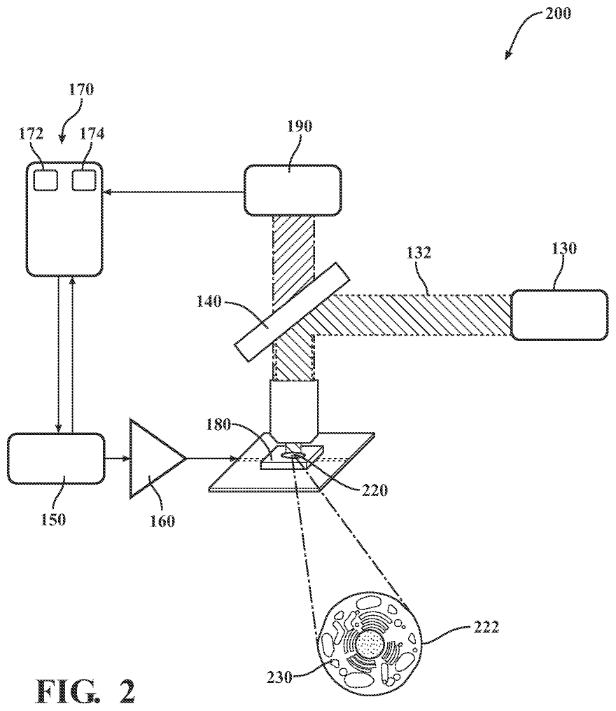

As discussed below in relation to FIGS. 1 and 2, the GaN quantum sensor can be implemented in various forms. For example, in one form, the GaN quantum sensor is configured as a chip, where a sample can be placed on the chip, i.e., the sample is in direct contact with the GaN quantum sensor. As used herein, the term “chip” refers to a layer (also known as a wafer) of semiconducting material with an embedded electronic circuit. In this form, the GaN quantum sensor is excited with a laser and radio frequency (RF) source (e.g., a microwave source) that modulates the GaN quantum sensor's fluorescence emission which can be analyzed to extract information relating to the sample. As another example, the GaN quantum sensor, in one form, is configured as a nanoparticle that is implanted in a sample. In this form, the GaN quantum sensor and the sample are excited with a laser and RF source that modulates the GaN quantum sensor's fluorescence emission which can be analyzed to extract information relating to the sample. In any case, the GaN quantum sensor is, in one or more non-limiting examples, configured to be operated at room temperature (i.e., between about 15 degrees Celsius (C) and about 25° C.).

Referring to FIG. 1, one non-limiting example of a quantum sensor system 100 (also referred to herein as “system 100”) is shown. The system 100 is, in one or more forms, configured to carry out optically detected magnetic resonance (ODMR) spectroscopy. In one or more variations, the system 100 includes a quantum device 110. As illustrated in FIG. 1, the quantum device 110 is, in one or more forms, a semiconductor chip that includes GaN. In at least one variation, the GaN includes a color center that is utilized by the system 100 to measure physical properties of a sample 120 disposed on the quantum device 110. As used herein, the phrase “color center” refers to a crystal defect which introduces or provides additional light absorption or light emission in crystalline materials. In some variations, the color center is an impurity, i.e., a foreign atom. In the alternative, or in addition to, the color center is a vacancy. The sample 120 is, for example, a biological sample, such as a droplet of blood, a skin cell, a fat cell, an electrical device, a power device, a catalyst, an electrolyte sample, and/or another suitable sample.

To measure physical properties of the sample 120, the system 100, in one or more variations, includes a laser source 130. In one form, the laser source 130 is an excitation source for the quantum device 110 and the sample 120, where the laser source 130 emits a laser beam 132 that contacts or illuminates the quantum device 110 that is direct contact with the sample 120. The laser beam 132 excites the electrons of the GaN color center which induces a fluorescence emission from the GaN color center. The laser source 130 is, in one or more forms, a 532 nm green laser. In other forms, the laser source 130 emits longer laser wavelengths, e.g., 594 nm, 612 nm, 633 nm, 647 nm, 694 nm, among others. For example, the laser source 130 may be an indium gallium nitride (InGaN) based laser or InGaN LED light source that emits a 532 nm green laser or a Krypton (Kr) based laser that emits 647 nm red laser. In one or more variations, the system 100 includes a dichroic mirror 140 or other reflective surface that reflects the laser beam 132 from the laser source 130 onto the quantum device 110/the sample 120.

The system 100 further includes, in one or more forms, a microwave source 150 that applies a microwave signal to the GaN color center during ODMR spectroscopy. The microwave signal is, in one form, amplified by an amplifier 160. In any case, the applied microwave signal causes changes in the spin state of the GaN color center and induces resonance transitions. Resonance transitions may modulate the fluorescence (e.g., the wavelength and/or intensity of the fluorescence) emitted by the quantum device 110. In one or more variations, a spectrometer 190 detects and analyzes the fluorescence emitted by the quantum device 110. The fluorescence intensity and/or wavelength is measured by the spectrometer 190 as a function of the microwave signal emitted by the microwave source 150. The collected fluorescence data can be collected using a computer or microcontroller 170 of the system 100. Changes in fluorescence as a function of the microwave signal provide insights regarding the sample 120. For example, in one or more variations, the fluorescence intensity can provide information relating to strength of a magnetic field of or in the sample 120, an electric field of or in the sample 120, the pH of the sample 120, and/or the temperature of the sample 120.

Referring now to FIG. 2, another non-limiting example of a quantum sensor system 200 (also referred to herein as “system 200”) is disclosed. In some variations, the system 200 is similar to the system 100 described above with respect to FIG. 1 and includes one or more of the laser source 130, dichroic mirror 140, the microwave source 150, amplifier 160, spectrometer 190, and computer 170 with a controller 172 and memory 174. However, and unlike the system 100, a sample 220 is disposed on a substrate 180 and a quantum device 230 is disposed within the sample 220. For example, and as illustrated in FIG. 2, the quantum device 230 is disposed within a biological cell 222. In addition, in at least one variation the quantum device 230 is a GaN nanoparticle with a color center that is utilized by the system 200 to measure physical properties of the sample 220 and/or biological cell 222. That is, one or more physical properties of the sample 220 and/or biological cell 222 are measured by exciting electrons of the GaN color center with a laser beam 132, which in turn induces a fluorescence emission from the GaN color center. And a microwave source 150 applies a microwave signal to the GaN color center such that the fluorescence intensity and/or wavelength measured by the spectrometer 190, as a function of the microwave signal, provides information on one or more physical properties of the sample 220 and/or biological cell 222. For example, in one or more variations, the fluorescence intensity can provide information relating to strength of a magnetic field of or in the sample 220 and/or biological cell 222, an electric field of or in the sample 220 and/or biological cell 222, the pH of the sample 220 and/or biological cell 222, and/or the temperature of the sample 220 and/or biological cell 222.

As noted above, in some variations the quantum devices discussed in relation to FIGS. 1 and 2 are formed from GaN. The GaN can be a doped GaN, and in some variations, the GaN is doped with Si, e.g., via Si doping during chemical vapor deposition growth or Si ion implantation. The GaN, in one or more non-limiting examples, includes about 10¹⁶ atoms of Si per cm³. Further, in one or more forms, the GaN has low C and O impurity. For example, in one non-limiting example, the GaN comprises less than about 8×10¹⁵ C atoms per cm³ and less than about 6×10¹⁵ O atoms per cm³. Additionally, in at least one variation, the Ga vacancy density is less than about 10¹⁶ vacancies per cm³. In one or more variations, the GaN has a color center with a ZPL between about 940 nm and about 960 nm. Non-limiting examples of the average ZPL of the GaN include an average ZPL between about 940 nm and about 960 nm, between about 945 nm and about 955 nm, between about 948 nm and about 955 nm, between about 948 nm and about 952 nm, and between about 949 nm and about 951 nm. In this way, the ZPL results in the GaN being suitable for biosensing.

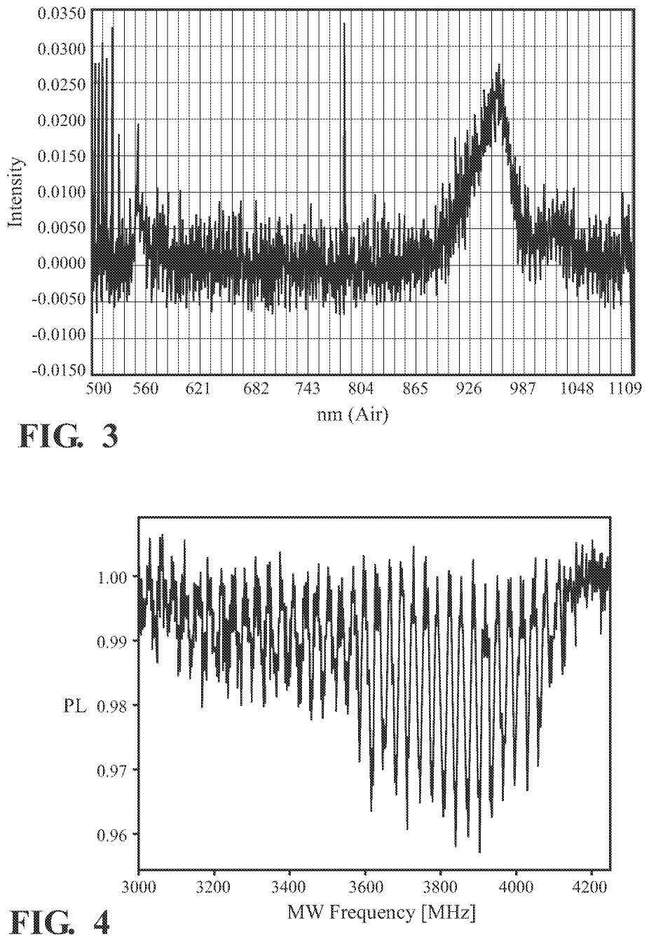

For example, and with reference to FIGS. 3 and 4, a photoluminescence spectra and ODMR spectra, respectively, obtained by subjecting a Si-doped GaN sample described in relation to FIGS. 1 and 2 to ODMR spectroscopy testing are shown. The Si-doped GaN sample had about 10¹⁶ atoms of Si per cm³, less than about 8×10¹⁵ C atoms per cm³, less than about 6×10¹⁵ O atoms per cm³, and a Ga vacancy density less than about 10¹⁶ vacancies per cm³. The laser used to obtain the photoluminescence spectra shown in FIG. 3 and the ODMR spectra shown in FIG. 4 was a 532 nm laser with a power output of 5 microwatts (mW). Further, the photoluminescence spectra and the ODMR spectra were collected at room temperature (i.e., between about 15° C. and about 25° C.). With reference to FIG. 3, the photoluminescence spectra is a plot of intensity versus frequency (nm) obtained from subjecting the GaN sample to the ODMR spectroscopy. As shown from the photoluminescence spectra, a peak, which represents the ZPL of the Si-doped GaN, occurred at a frequency between about 940 nm and about 960 nm.

With reference to FIG. 4, the ODMR spectra is a plot of photoluminescence (PL) versus microwave frequency (MHz) obtained from subjecting the Si-doped GaN sample to the ODMR spectroscopy. As shown from the ODMR spectra, an optical contrast peak occurred at about 3,850 MHz. The optical contrast peak is a point at which the Si-doped GaN sample experienced a change in intensity due to the spin state of the Si-doped GaN sample caused by emitted microwave signals during ODMR spectroscopy. The existence of the optical contrast peak validates that a Si-doped GaN quantum sensor with a ZPL between about 940 nm and about 960 nm can function at room temperature. In this way, the Si-doped GaN quantum sensor with a ZPL between about 940 nm and about 960 nm is utilized at room temperature to measure physical properties (e.g., temperature and magnetic field strength) of samples, such as biological samples and battery electrolytes.

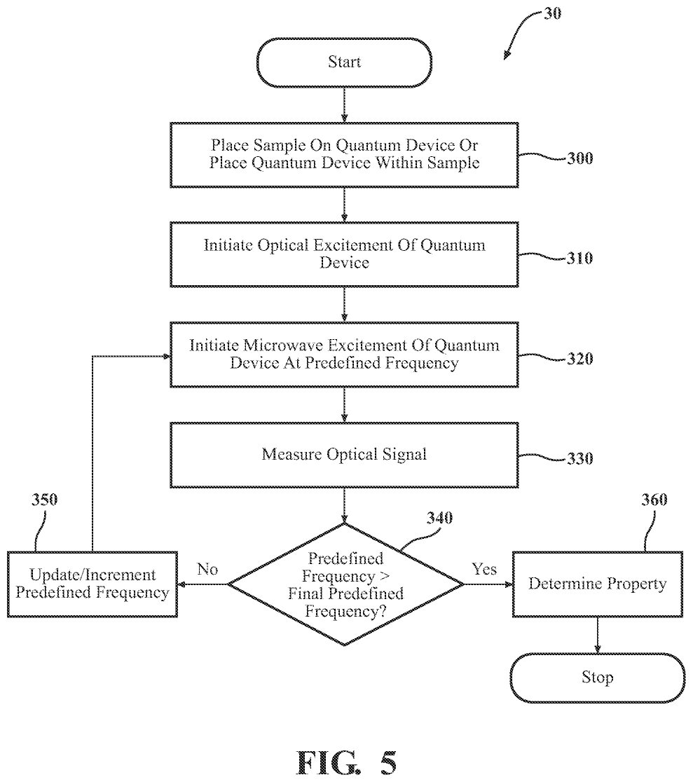

Referring to FIG. 5, and with reference to FIGS. 1-2, a method 30 for determining a property of a sample using the system 100 and/or 200 is shown. The method 30 includes placing a sample 120 on a quantum device 110 (FIG. 1) or placing a quantum device 230 in a sample 220 (FIG. 2) at 300, and initiating optical excitement of the quantum device 110, 230 with a light source at 310. A microwave source initiates microwave excitement of the quantum device 110, 230 with a predefined frequency at 320, and an optical signal from the optically and microwave excited quantum device 110, 230 (e.g., the optical signal intensity) is measured with an optical detector at 230. The method 30 includes determining if the predefined frequency in step 320 is greater than a final predefined frequency at 340, and if the predefined frequency in step 320 is not greater than the final predefined frequency, the method 30 updates and/or increments the predefined frequency at 350 and returns to 320 where the quantum device 110, 230 is microwave excited with the updated/increment microwave signal. This cycle, i.e., 320-330-340-350-320, continues until the predefined frequency is greater than the predefined final frequency. And when the predefined frequency is greater than the predefined final frequency at 340, the method 30 determines a predefined property of the sample 120, 220 at 360. In some variations, the computer 170 calculates a value (e.g., using the controller 172) for the predefined property using one or more equations stored in memory 174. In the alternative, or in addition to, the computer 170 determines a value (e.g., using the controller 172) for the predefined property from a look-up table stored in memory 174. In this manner, the system 100, system 200 and/or method 30 measure an optical signal from the optically and microwave excited quantum device 110, 230 as a function of a property of the sample 120, 220, respectively.

The preceding description is merely illustrative in nature and is in no way intended to limit the disclosure, its application, or uses. Work of the presently named inventors, to the extent it may be described in the background section, as well as forms and/or variations of the description that may not otherwise qualify as prior art at the time of filing, are neither expressly nor impliedly admitted as prior art against the present technology.

As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range.

The headings (such as “Background” and “Summary”) and sub-headings used herein are intended only for general organization of topics within the present disclosure, and are not intended to limit the disclosure of the technology or any form or variation thereof. The recitation of multiple forms or variations having stated features is not intended to exclude other forms or variations having additional features, or other forms or variations incorporating different combinations of the stated features.

As used herein the term “about” when related to numerical values herein refers to known commercial and/or experimental measurement variations or tolerances for the referenced quantity. In some variations, such known commercial and/or experimental measurement tolerances are +/−10% of the measured value, while in other variations such known commercial and/or experimental measurement tolerances are +/−5% of the measured value, while in still other variations such known commercial and/or experimental measurement tolerances are +/−2.5% of the measured value. And in at least one variation, such known commercial and/or experimental measurement tolerances are +/−1% of the measured value.

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The sensors, systems, components, controllers, computers and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a ROM, an EPROM or flash memory, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain or store a program for use by or in connection with an instruction execution system, apparatus, or device.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one form or variation, or various forms or variations means that a particular feature, structure, or characteristic described in connection with the form or variation or particular system is included in at least one form or variation of the present disclosure. The appearances of the phrase “in one form” or “in one variation” (or variations thereof) are not necessarily referring to the same form or variation. It should be also understood that the various method steps discussed herein do not have to be carried out in the same order as depicted, and not each method step is required in each form or variation.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A quantum sensor comprising:
a quantum device comprising gallium nitride (GaN) with a color center, the color center having a zero-phonon line (ZPL) between about 900 nanometers (nm) and about 990 nm.

2. The quantum sensor of claim 1, wherein the GaN is silicon (Si) doped.

3. The quantum sensor of claim 2, wherein the GaN includes about 10¹⁶ atoms of Si per cubic centimeter (cm³).

4. The quantum sensor of claim 1, wherein the quantum device is configured to operate at between about-40 degrees Celsius (° C.) and about 100° C.

5. The quantum sensor of claim 1, wherein the GaN comprises less than about 8×10¹⁵ carbon (C) atoms per cm³.

6. The quantum sensor of claim 1, wherein the GaN comprises less than about 6×10¹⁵ oxygen (O) atoms per cm³.

7. The quantum sensor of claim 1, wherein the ZPL of the GaN is between about 948 nm and about 955 nm.

8. The quantum sensor of claim 1, wherein the ZPL of the GaN is between about 949 nm and about 951 nm.

9. The quantum sensor of claim 1, wherein the quantum device is configured to measure a temperature of a sample.

10. The quantum sensor of claim 1, wherein the quantum device is configured to measure a magnetic field strength of a sample.

11. The quantum sensor of claim 1 further comprising a biological sample, wherein the quantum device is in contact with the biological sample and is configured to measure at least one of a temperature and a magnetic field strength of the biological sample.

12. The quantum sensor of claim 1 further comprising a battery electrolyte, wherein the quantum device is in contact with the battery electrolyte and is configured to measure at least one of a temperature and a magnetic field strength of the battery electrolyte.

13. A quantum sensor comprising:
a quantum device comprising gallium nitride (GaN) with a color center, the color center having a zero-phonon line (ZPL) between about 900 nanometers (nm) and about 990 nm, the GaN being Si-doped, and the quantum device configured to operate at between about 15 degrees Celsius (° C.) and about 25° C.

14. The quantum sensor of claim 13, wherein the ZPL of the GaN is between about 940 nm and about 960 nm.

15. The quantum sensor of claim 13, wherein the ZPL of the GaN is between about 948 nm and about 955 nm.

16. The quantum sensor of claim 13, wherein the quantum device is configured to measure a temperature of a sample.

17. The quantum sensor of claim 13, wherein the quantum device is configured to measure a magnetic field strength of a sample.

18. The quantum sensor of claim 13 further comprising a biological sample, wherein the quantum device is configured to measure at least one of a temperature and a magnetic field strength of the biological sample.

19. The quantum sensor of claim 13 further comprising a battery electrolyte, wherein the quantum device is configured to measure at least one of a temperature and a magnetic field strength of the battery electrolyte.

20. A quantum sensor comprising:
a quantum device comprising doped gallium nitride (GaN) with a color center, the color center having a zero-phonon line (ZPL) between about 940 nanometers (nm) and about 960 nm, the doped GaN being Si-doped with about 10¹⁶ atoms of Si per cm³, having less than about 8×10¹⁵ C atoms per cm³ and less than about 6×10¹⁵ O atoms per cm³, wherein the quantum device is configured to operate between about 15 degrees Celsius (C) and about 25° C., and measure at least one of a temperature and a magnetic field strength of a sample.
